(19) United States
(12) Patent Application Publication
(10) Pub. No.: US 2015/0216061 A1
(43) Pub. Date: Jul. 30, 2015

(54) Components and methodology for producing custom-sized, small aluminum modular chassis based on a single design and production process

(71) Applicants: David Flores, McKinney, TX (US); Kendall Saer Ford, Sherman, TX (US)

(72) Inventors: David Flores, McKinney, TX (US); Kendall Saer Ford, Sherman, TX (US)

(21) Appl. No.: 14/166,901

(22) Filed: Jan. 29, 2014

(51) Int. Cl. H05K 5/00; H05K 5/04

(52) U.S. Cl. CPC H05K 5/0004; H05K 5/04

(57) ABSTRACT

Components and methodology for producing custom-sized, small aluminum modular chassis based on a single design and production process is disclosed. The unique designs of the components and the modularity of the design allow for the cost-effective production of varying size chassis. A broad range of chassis sizes can be produced without the need to modify the production setup and can be produced with basic, relatively inexpensive machinery. All components and extrusion profiles are unique to the design and assembly of the chassis.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE OR A COMPUTER PROGRAM LISTING COMPACT DISC APPENDIX

Not Applicable

### BACKGROUND OF THE INVENTION

The invention pertains to the manufacture of small aluminum chassis, also referred to as enclosures, which are typically used in/on which to construct electrical and or electro-mechanical assemblies. Chassis of this sort are often used in the construction of audio electronics projects, computer peripheral projects and general electronics assembly projects.

The invention reduces the time and effort required to produce custom-sized small aluminum chassis using basic, relatively inexpensive machinery. Many different sizes of the invention can be made using a single set of equipment and tools. The invention solves the problem of needing to redesign a preexisting chassis and/or re-tool a production setup to produce each unique size.

### BRIEF SUMMARY OF THE INVENTION

The invention is a chassis design based on a specific extruded aluminum shape that simplifies the production of custom-sized aluminum chassis. Using this specific aluminum extrusion and specific brackets, chassis are made to different sizes using a single production setup and process. The aluminum extrusion is used to form the sides of a chassis which are held together with the specific brackets. Aluminum sheet, or other material, is used to make the top and bottom cover plates of the chassis.

The aluminum extrusion is of a specific thickness and specific shape. Different versions of the aluminum extrusion vary from one another by the overall length across the extrusion profile. The overall length across the extrusion profile sets the height of a chassis. As of this writing, chassis with heights of 2.25 inches, 3.25 inches and 4.25 inches have been made. Additionally, an extrusion profile for a chassis height of 5.20 inches is being built. The width and depth of a chassis are limited only by the production equipment used and by the extruded linear length of the extrusion being used. Additionally, the width and depth of a chassis are limited by the available size of aluminum sheet that is used for the top and bottom cover plates.

All components of the design, excluding the screws required for assembly, are made from 0.125 inch thick, tempered 6061 aluminum alloy.

Many of the preexisting aluminum chassis designs are available only in a limited set of sizes. Other preexisting aluminum chassis designs require redesign and/or retooling to produce uniquely sized chassis. Still other preexisting aluminum chassis designs have parts made of different material that is either thicker or thinner than the invention. The thickness of the material used in the invention provides for a rugged chassis while still being easy to machine and accommodates the mounting of typical off-the-shelf components.

The invention facilitates the quick and simple production of a chassis of any size within the limits of the production setup and material available.

### BRIEF DESCRIPTION OF THE SEVERAL VIEWS OF THE DRAWINGS

FIG. 1 shows the reference characters with descriptions of the items to which they refer.

FIG. 2A shows the top view of the extrusion that has been machined for a front or back chassis piece.

FIG. 2B shows the end view of the extrusion that has been machined for a front or back chassis piece.

FIG. 2C shows the front view of the extrusion that has been machined for a front or back chassis piece.

FIG. 3A shows the top view of the extrusion that has been machined for a front or back chassis piece along with the Corner Brackets installed.

FIG. 3B shows the front view of the extrusion that has been machined for a front or back chassis piece along with the Corner Brackets installed.

FIG. 4 shows the front view of the extrusion that has been machined for a front or back chassis piece along with the Corner Brackets, the screws, the Top Plate and the Bottom Plate installed.

FIG. 5A shows the top view of the extrusion that has been machined for a side chassis piece.

FIG. 5B shows the front view of the extrusion that has been machined for a side chassis piece.

FIG. 5C shows the end view of the extrusion that has been machined for a side chassis piece.

FIG. 6A shows the top view of the extrusion that has been machined for a side chassis piece along with the Corner Brackets installed.

FIG. 6B shows the front view of the extrusion that has been machined for a side chassis piece along with the Corner Brackets installed.

FIG. 7 shows the side view of a chassis assembled with the optional Face Brackets and a flat front or back piece.

FIG. 8 shows the top view of a chassis that is made from the aluminum extrusion and the Corner Brackets.

FIG. 9 shows the bottom view of a chassis that is made from the aluminum extrusion with the Corner Plates installed.

FIG. 10A shows an exploded view of the top of a chassis that is made from the aluminum extrusion and the Corner Brackets.

FIG. 10B shows an exploded view of Section 1-1 from FIG. 10A. “Section A-A” sited in this figure is incorrect and should be “Section 1-1.”

FIG. 10C shows an assembled view of Section 1-1 from FIG. 10A. “Section A-A” sited in this figure is incorrect and should be “Section 1-1.”

FIG. 11A shows the end view of the extrusion and indentifies the surface area that is exposed on an assembled chassis.

FIG. 11B shows the end view of the extrusion along with the dimensions and specifications for manufacturing the aluminum extrusion.

FIG. 12A shows the top view of the Corner Bracket along with the dimensions and specifications for manufacturing the Corner Bracket.

FIG. 12B shows the front view of the Corner Bracket along with the dimensions for manufacturing the Corner Bracket.

FIG. 13A shows the top view of the Face Bracket along with the dimensions and specifications for manufacturing the Face Bracket.

FIG. 13B shows the front view of the Face Bracket along with the dimensions for manufacturing the Face Bracket.

FIG. 13C shows the side view of the Face Bracket along with the dimensions for manufacturing the Face Bracket.

FIG. 14 shows the top view of the Corner Plate along with the dimensions and specifications for manufacturing the Corner Plate.

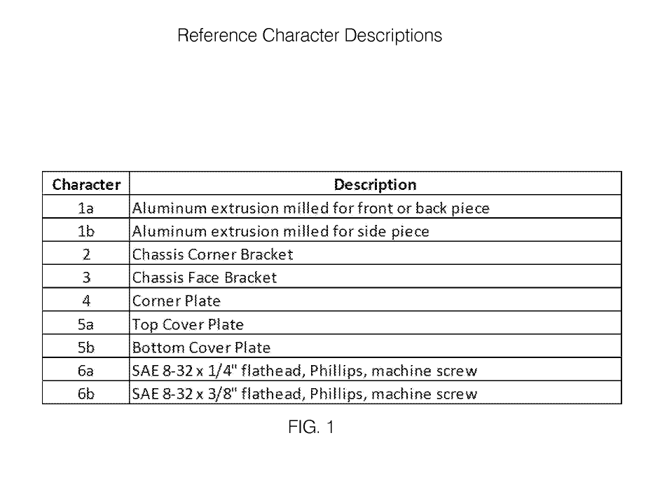

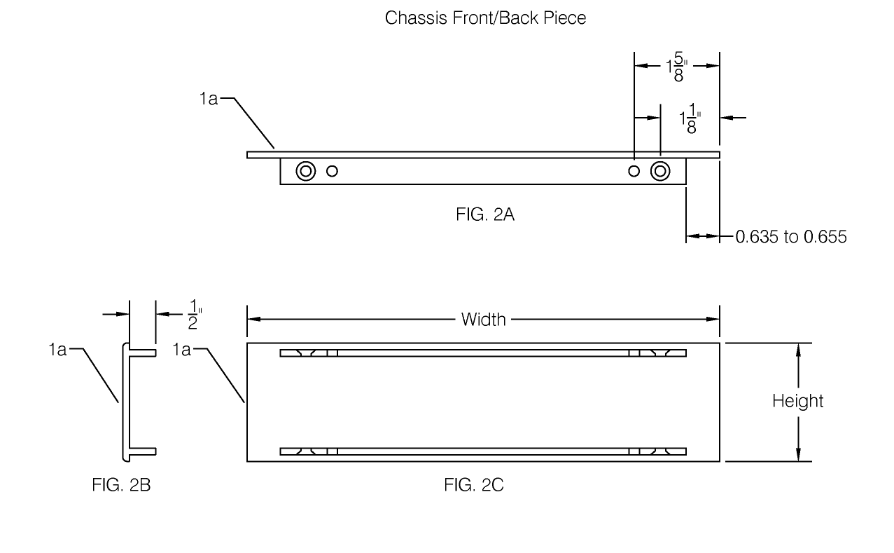

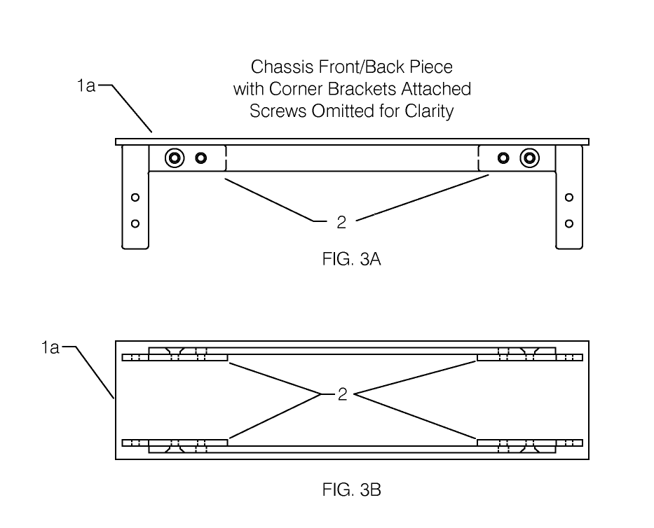

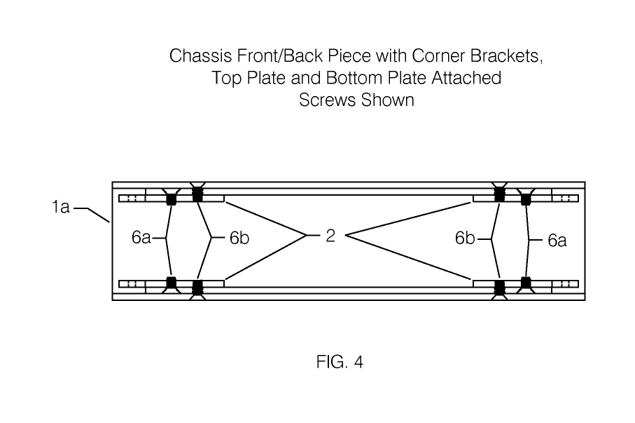

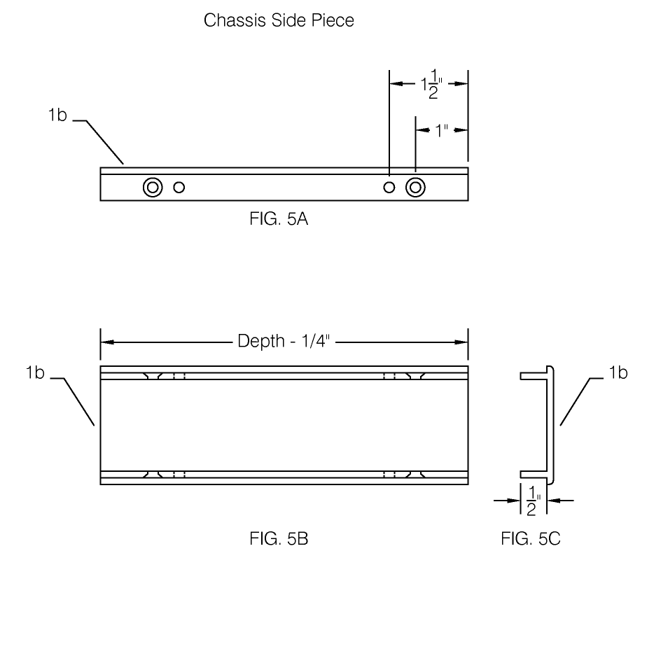

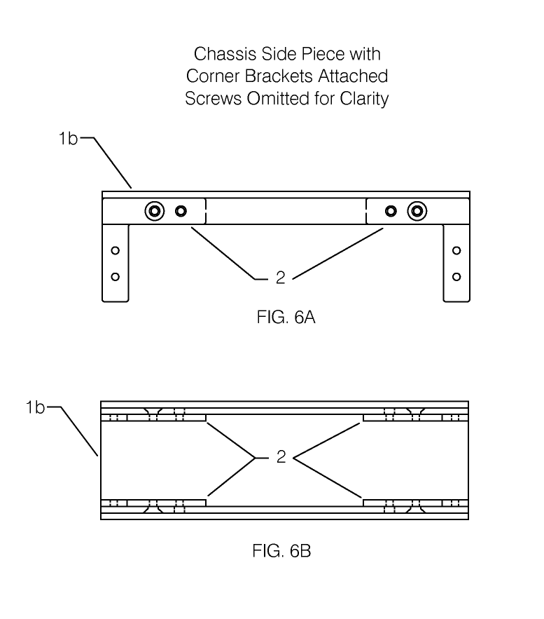

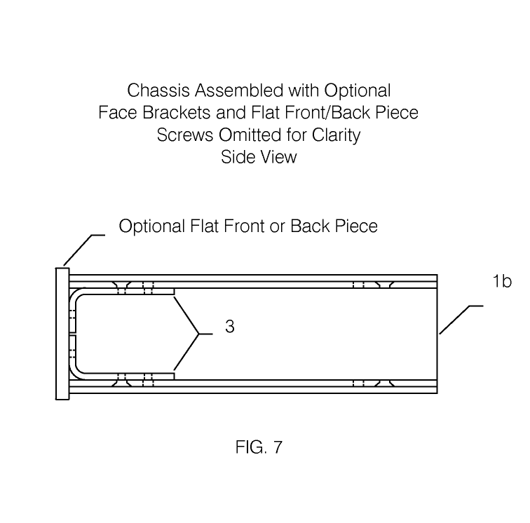

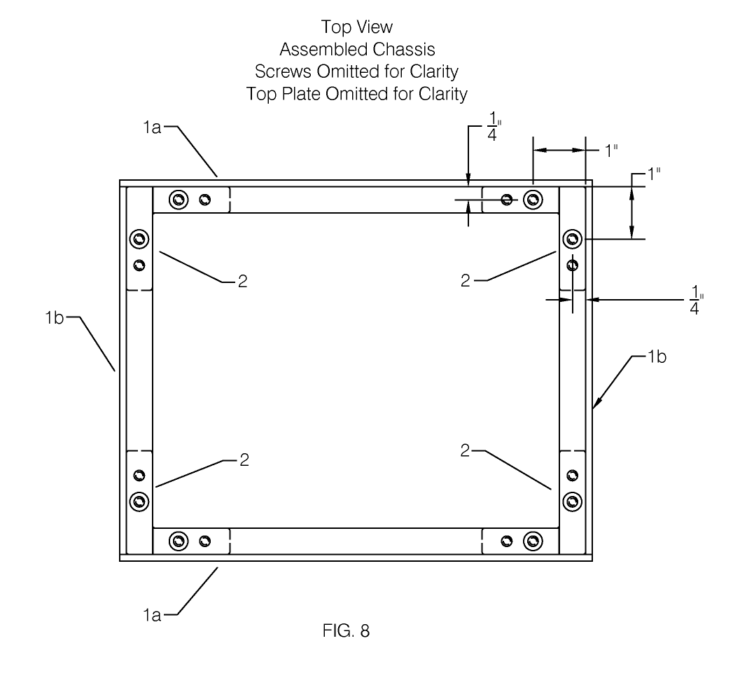

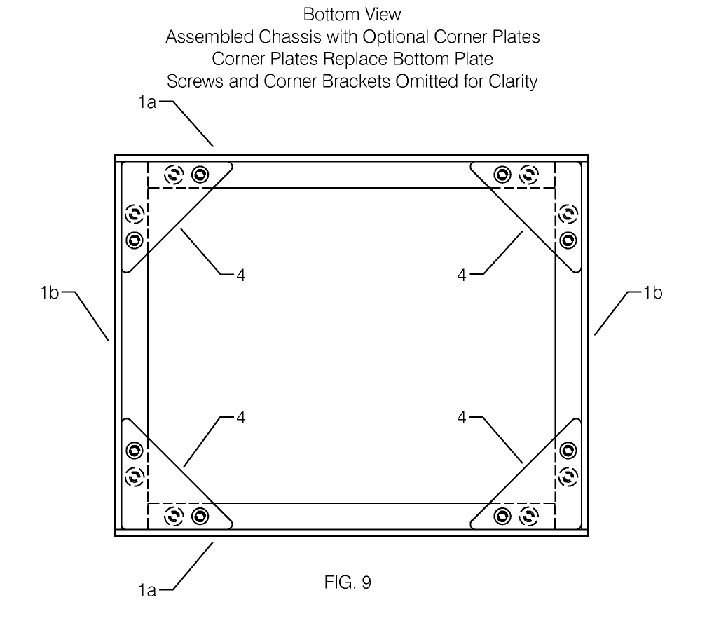

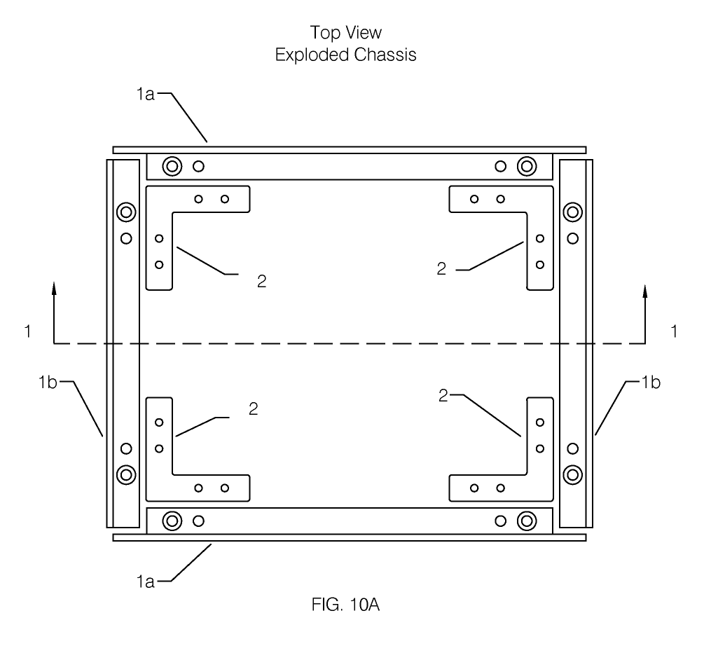

### DETAILED DESCRIPTION OF THE INVENTION

Drawing page 1/16 is a table of reference characters with descriptions of the items to which they refer. These reference characters are used in the subsequent pages of the drawings.

Drawing page 2/16 shows the extrusion machined for a front or back chassis piece. The front and back pieces are identical and interchangeable. The width shown is made by cutting the extrusion to the desired dimension. The minimum overall chassis depth is 4.25″ and is limited by the Corner Brackets that are required for assembly. The height shown is selected from available extrusion sizes and is the only dimension of the chassis that is not cut to size. The notches at the ends of the extrusion are milled into what is referred to as the extrusion tabs. These notches in the tabs allow the front/back chassis piece to overlap the side chassis pieces.

Drawing page 3/16 shows a chassis front or back piece with Corner Brackets attached. The Corner Brackets facilitate assembly of the chassis front, back and side pieces. The screws that hold the pieces together are omitted from this view.

Drawing page 4/16 shows a chassis front or back piece with Corner Brackets, top plate and bottom plate attached. The screws that hold the pieces together are shown in this view.

Drawing page 5/16 shows the extrusion machined for a side chassis piece. The two sides (left and right) are identical and interchangeable. The dimension identified as Depth −¼″ is ¼″ less than the overall depth of the chassis. The Depth −¼″ dimension is made by cutting the extrusion to the desired dimension. The minimum overall chassis depth is 4.25″ and is limited by the Corner Brackets that are required for assembly.

Drawing page 6/16 shows a chassis side piece with Corner Brackets attached. The screws that hold the pieces together are omitted from this view.

Drawing page 7/16 shows a chassis side piece with Face Brackets installed on one end instead of the Corner Brackets that are shown in the other views. The Face Brackets facilitate attachment of a flat front or back piece that is made from something other than the aluminum extrusion. The screws that hold the pieces together are omitted from this view.

Drawing page 8/16 shows the top view of a chassis that is made from the aluminum extrusion and the Corner Brackets. This view shows the extrusion front piece, back piece, two side pieces and the Corner Brackets. The screws that hold the pieces together are omitted from this view. The top plate, if used, is also omitted from this view.

Drawing page 9/16 shows the bottom view of a chassis that is made from the aluminum extrusion and the Corner Brackets. This view shows the extrusion front piece, back piece, two side pieces, Corner Brackets and Corner Plates. The Corner Brackets and the screws that hold the pieces together are omitted from this view. In this view, four Corner Plates are shown instead of a solid bottom plate. The Corner Plates leave most of the chassis bottom open.

Drawing page 10/16 shows an exploded view of the top of a chassis that is made from the aluminum extrusion and the Corner Brackets. This view shows the extrusion front piece, back piece, two side pieces and the Corner Brackets. The screws that hold the pieces together are omitted from this view. The top plate, if used, is also omitted from this view.

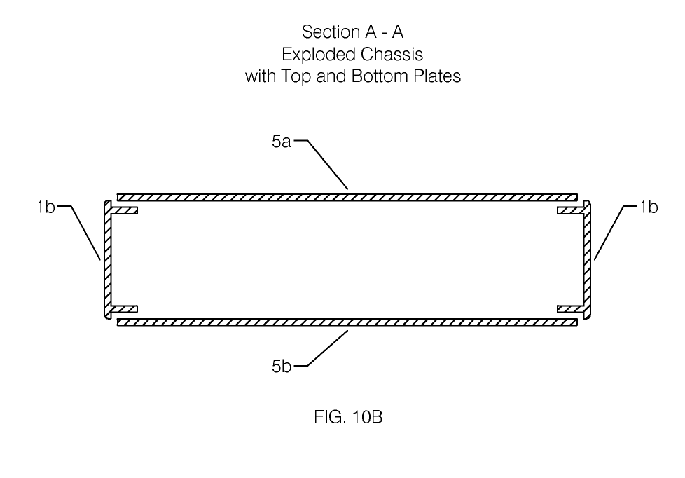

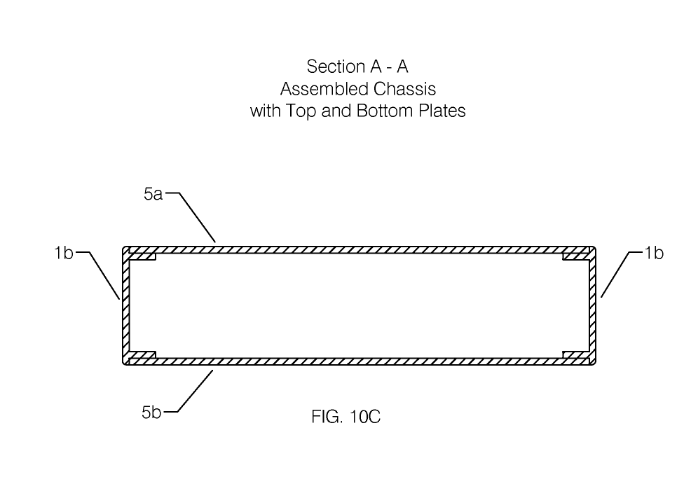

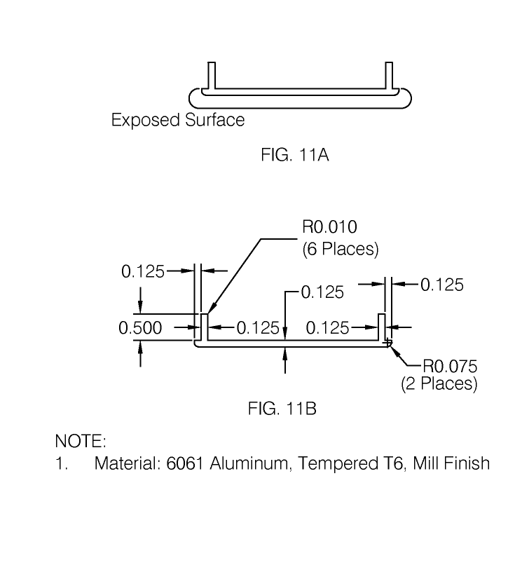

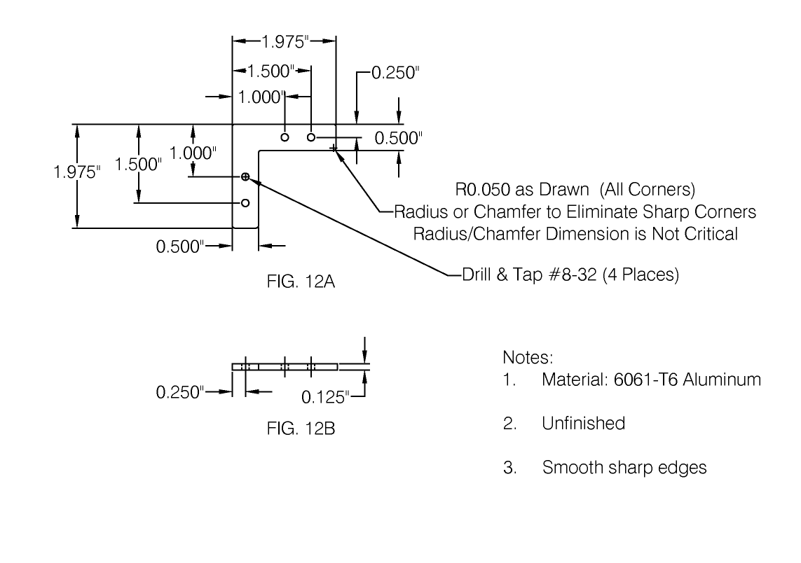

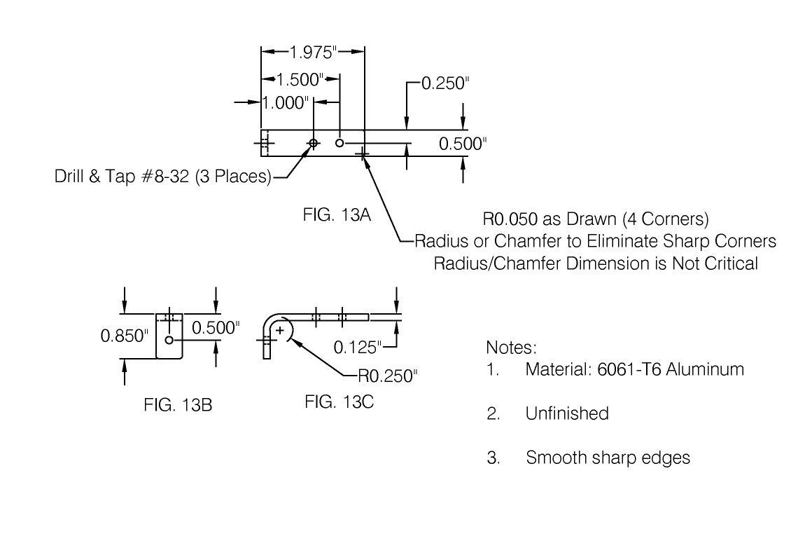

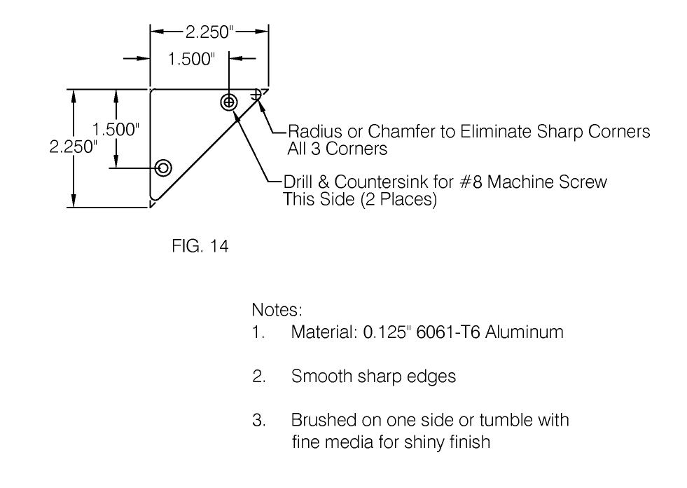

Drawing page 11/16 shows an exploded view of Section 1-1 from FIG. 10A. This view shows the chassis side pieces, top plate and bottom plate.

Drawing page 12/16 shows an assembled view of Section 1-1 from FIG. 10A. This view shows the chassis side pieces, top plate and bottom plate.

Drawing page 13/16 shows the dimensions, specifications and manufacturing notes of the aluminum extrusion.

Drawing page 14/16 shows the dimensions, specifications and manufacturing notes of the Corner Brackets.

Drawing page 15/16 shows the dimensions, specifications and manufacturing notes of the Face Brackets.

Drawing page 16/16 shows the dimensions, specifications and manufacturing notes of the Corner Plates.

The invention reduces the time and effort required to produce custom-sized, small aluminum chassis. The specific aluminum extrusion and the Corner Brackets are the fundamental components of the invention that facilitate the reduction in time and effort. The design of the invention eliminates the need to redesign the chassis and/or re-tool the equipment to produce each unique size chassis. Every size chassis is made on one common set of equipment where the only adjustments made are for varying cut lengths. All other machining operations are made on pre-configured equipment that does not change regardless of chassis size. Because of the unique design of the invention, the production effort is virtually the same for any size chassis.

The design of the invention makes for an aesthetically pleasing chassis. Once assembled, all visible screws are in the cover plates of the chassis. Many existing products have more visible screws than this design. Also, many existing design have visible screws in the front piece of the chassis which is often deemed undesirable.

Simplicity and a minimum of different parts are key aspects of the invention. They allow for a common manufacturing process and assembly process to be used for any size chassis. Adding more components or elements would not improve the invention.

The invention is designed specifically to facilitate the rapid production of unique single units. Width and depth of a chassis can be easily made to any dimension within the limits of the production equipment. Height is determined by the aluminum extrusions that have been produced based on the design of the invention.

All aluminum parts used in a chassis are made of 0.125″ thick material.

The specific thickness of the material results in a chassis that is strong and rugged while still thin enough to accommodate most standard off-the-shelf electrical connectors, components and accessories that would be attached to the chassis.

The invention differs from what currently exists in that the invention is easier to make, quicker to make and less costly to make than most similar products. The design of the invention makes for a robust chassis that can withstand the rigors of many different applications. The invention can be produced in a range of sizes not typically offered by most existing products that are similar to the invention.

The invention discussed here includes the following components. The processed listed are used to produce the invention.
1. Aluminum alloy 6061-T6 extrusion of the specified shape

a. Aluminum extrusion milled for front or back piece

b. Aluminum extrusion milled for side piece
2. Chassis Corner Bracket, aluminum alloy 6061-T6
3. Chassis Face Bracket, aluminum alloy 6061-T6
4. Corner Plate, aluminum alloy 6061-T6
5. Cover Plate, aluminum alloy 6061-T6

a. Top cover plate

b. Bottom cover plate
6. Standard off-the-shelf machine screws, stainless steel

a. SAE 8-32×¼″ Flathead, Philips

b. SAE 8-32×⅜″ Flathead, Philips
7. Process to cut the extrusion to custom lengths
8. Process to mill notches in the ends of the extrusion tabs to make front pieces and back pieces to common dimensions
9. Process to drill and countersink holes in the extrusion pieces to common dimensions
10. Process to cut the Top Plate and/or the Bottom Plate to custom dimensions
11. Process to drill and countersink holes in the Top Plate and/or the Bottom Plate to common dimensions
12. Process to assemble the chassis

The following paragraphs describe the relationships between the components. To begin with, Item 1 and Item 2 are the basic components of the invention, they allow all sizes of chassis to be made and assembled in the same way. Two pieces of Item 2 attach to a piece of Item 1a and piece of Item 1b to form a corner of a rectangular chassis. The pieces are held together with machine screws identified as Item 6a. Two pieces of Item 1a, 2 pieces of Item 1b and eight pieces of Item 2 are required to assemble a complete rectangular chassis with four sides but no top or bottom cover plate.

Item 3 offers the option to eliminate the front and/or rear piece of extrusion and substitute a flat plate that is not made from the extrusion. This offers versatility in the end product, but also requires more time and effort to manufacture the front and/or rear piece. Item 3 is an optional component of the invention.

Item 4 can be used in place of the Item 5b if the bottom of the chassis is to be left open. Item 4 serves as a surface on which to attach support feet. Item 4 also strengthens the corners of the chassis if Item 5b is to be omitted. Item 4 is an optional component of the invention.

Item 5a attaches to Item 1 and Item 2 and covers the top of the chassis. Item 5b attaches to Item 1 and Item 2 and covers the bottom of the chassis.

Item 6 holds the pieces together. Standard off-the-shelf screws are used for Item 6 and can therefore be easily sourced for production and replacement parts.

Item 7 is a process for cutting item 1a and Item 1b to size. To make a square and accurately sized chassis, an industrial chop saw with a precision fence is used for this process. The fence is adjusted to the required length, the extrusion piece is loaded onto the saw table and the piece is cut to length. This process is conducted in the same manner for any size chassis.

Item 8 is a process that is performed on item 1a to create notches in the ends of the extrusion tabs. This process is performed with a vertical mill and a jig that holds the extrusion in a precise manner. The milling operation is performed across each end of Item 1a in two passes to remove between 0.635 inch and 0.655 inch of the extrusion tabs. This notching of the extrusion tabs allows the chassis to be assembled with the front and back pieces overlapping the side pieces. This notching process is the same for every front and back piece.

Item 9 is a process that is performed on Item 1a and Item 1b. This process creates holes and countersunk holes through which to install the machine screws defined as Item 6. Item 1a is drilled and countersunk to different dimensions than Item 1b. Drawing 2/16 and Drawing 5/16 show the hole placement in Item 1a and Item 1b respectively. The drill and countersink process is the same for every Item 1a and is the same for every Item 1b. This process can be performed on a drill press or vertical mill and requires the use of a jig to hold the parts in a consistent position. This process for the invention is performed on a small vertical mill which produces repeatable results. One jig is used for making the holes in Item 1a and another jig is used for making the holes in Item 1b.

Item 10 is a process that is performed to create the chassis cover plates defined as Item 5a and Item 5b. This process is not unique to the invention and can be performed in a number of different ways. The cover plates of the invention are created using a table saw with an accurate fence. The fence used can be adjusted to the nearest 0.001 inch. The accuracy and repeatability of the fence ensures the cover plates are sized correctly. This is not only essential for proper fit and finish, but also to correctly accommodate the process defined in Item 11. The cover plates must be sized accurately to allow the holes created in the next process to properly align with the holes created in the process of Item 9 and the holes in Item 2 and/or the holes in Item 3.

Item 11 is a process that is performed on the chassis cover plates defined as Item 5a and Item 5b. This process is performed to drill and countersink holes in the cover plates. The holes accommodate screws defined as Item 6 that are used to attach the cover plates to the chassis. Drawing 8/16 shows the dimensions of the cover plate holes from the edges of the cover plate. This process of drilling and countersinking holes is performed on a drill press with a fixed jig. The jig is set so the position and depth of the corner holes is the same for each cover plate, regardless of size.

Item 12 is the process of assembling the chassis. This process is not considered part of the production process but instead is left to the end user. This process is described here for completeness. Two pieces of Item 1a, 2 pieces of Item 1b and eight pieces of Item 2 are required to assemble a complete rectangular chassis with four sides but no top or bottom cover plate. Additionally, the machine screws identified as Item 6a are used to hold the pieces together. The chassis cover plates, Item 5a and Item 5b, are held to the chassis with the machine screws identified as item 6b. Drawings 8/16, 9/16, 10/16, 11/16 and 12/16 show the assembly of chassis pieces.

Use of the invention varies from person to person. The invention was designed to give the average hobbyist or professional a mechanical foundation on which to build an electronics project. The aluminum material of the invention can be easily drilled or cut as needed to mount various components on or inside the chassis.

The design of the invention accommodates variations from the simple rectangular chassis described so far. For example, a rectangular chassis can be divided into sections with the use of an additional piece of the extrusion that serves as a divider. The divider is placed between the sides or between the front and back pieces of the chassis. Where it is placed, a notch is milled into the tabs of two pieces of Item 1a or Item 1b. The divider has holes drilled and countersunk into it as would a piece of Item 1b and is held in place with 4 Corner Brackets. The cover plates are then sized to fit the divided sections of the chassis. The holes in the cover plates are drilled and countersunk just as they are for a typical rectangular chassis.

Because the invention uses an off-the-shelf product for the cover plates, other readily available materials can be used. Another material with a nominal thickness of 0.125″ can be used for the cover plates instead of the specified aluminum alloy. Brass and copper are often desired for use as the top cover plate.

1. The invention differs from what currently exists. Following are the claims of the invention.
1. The uniqueness of the components and the modularity of the design lead to the cost-effective production of varying size chassis
2. The shape of the aluminum extrusion is unique
3. The design of the Corner Brackets is unique
4. The design of the Face Brackets is unique
5. The assembly of the parts to create a chassis is unique
